(19) United States
(12) Patent Application Publication
(10) Pub. No.: US 2026/0362951 A1
(43) Pub. Date: Nov. 12, 2026

(54) DISPLAY DEVICE

(71) Applicant: LG Display Co., Ltd., Seoul (KR)

(72) Inventors: Heesu BYEON, Paju-si (KR); Goeun LIM, Paju-si (KR); Saemi PARK, Paju-si (KR)

(73) Assignee: LG Display Co., Ltd., Seoul (KR)

(21) Appl. No.: 19/643,476

(22) Filed: Apr. 9, 2026

(30) Foreign Application Priority Data
May 8, 2025 (KR) 10-2025-0059729

(51) Int. Cl. H10K 59/80; H10K 59/35; H10K 59/38; H10K 59/95; H10K 102/00

(52) U.S. Cl. CPC H10K 59/879; H10K 59/35; H10K 59/38; H10K 59/80515; H10K 59/80521; H10K 59/80522; H10K 59/95; H10K 2102/351

(57) ABSTRACT

A display device can include a substrate having at least one sub-pixel including a light-emitting area and a non-light-emitting area around the light-emitting area, a first organic light-emitting element over the substrate in the light-emitting area, a second organic light-emitting element over the first organic light-emitting element, and a lens between the first organic light-emitting element and the second organic light-emitting element.

### CROSS-REFERENCE TO RELATED APPLICATION

The present application claims priority to Korean Patent Application No. 10-2025-0059729, filed in the Republic of Korea on May 8, 2025, the entire contents of which is expressly incorporated by reference herein for all purposes.

### BACKGROUND

### Field of the Invention

The present disclosure relates to a display device.

### Discussion of the Background Art

As the information society develops, various demands for display devices for displaying images are increasing, and various types of display devices such as liquid crystal display (LCD) devices and organic light emitting diode (OLED) display devices are utilized.

Among the display devices, there is an advantage in that the OLED displays as the self-luminous types have superior viewing angles and contrast ratios than the LCDs, and are lighter and thinner and have low power consumption because they do not require a separate backlight. In addition, there is an advantage in that the OLED displays can drive at a low direct current voltage, have a fast response speed, and especially low manufacturing costs.

Recently, demand for a display device that needs augmented reality (AR), virtual reality (VR), or equivalent ultra-high resolution using such an OLED display device is increasing.

### SUMMARY OF THE DISCLOSURE

Various embodiments of the present disclosure are directed to providing a display device with improved optical efficiency.

Various embodiments of the present disclosure are also directed to providing a display device with high luminance and excellent color reproducibility.

Various embodiments of the present disclosure are also directed to providing a low-power display device.

Various embodiments of the present disclosure provide an improved display device, which address the limitations and disadvantages associated with the related art.

Objects of the present disclosure are not limited to the above-described objects, and other technical objects can be inferred from the following embodiments.

According to one embodiment of the present disclosure, there is provided a display device including a substrate having at least one sub-pixel including a light-emitting area and a non-light-emitting area around the light-emitting area, a first organic light-emitting element over the substrate in the light-emitting area, a second organic light-emitting element over the first organic light-emitting element, and a lens between the first organic light-emitting element and the second organic light-emitting element.

According to another embodiment of the present disclosure, there is provided a display device including a substrate having at least one sub-pixel including a light-emitting area and a non-light-emitting area around the light-emitting area, a first organic light-emitting element on the substrate in the light-emitting area, a second organic light-emitting element on the first organic light-emitting element, and a color filter between the first organic light-emitting element and the second organic light-emitting element.

Detailed matters of other embodiments of the present disclosure are included in the detailed description and accompanying drawings.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to one embodiment of the present disclosure.

FIG. 2 is an example of a plan view of a pixel in FIG. 1.

FIG. 3 is an example of a cross-sectional view along line A-A’ in FIG. 2.

FIG. 4 is an example of a cross-sectional view along line B-B’ in FIG. 2.

FIG. 5 is an example of a schematic view illustrating an optical path in FIG. 2.

FIG. 6 is a cross-sectional view along line B-B’ of a pixel of a display device according to another embodiment of the present disclosure.

FIG. 7 is a cross-sectional view along line A-A’ of a pixel of a display device according to still another embodiment of the present disclosure.

FIG. 8 is a cross-sectional view along line A-A’ of a pixel of a display device according to yet another embodiment of the present disclosure.

FIG. 9 is a cross-sectional view along line A-A’ of a pixel of a display device according to yet another embodiment of the present disclosure.

FIG. 10 is a cross-sectional view along line A-A’ of a pixel of a display device according to yet another embodiment of the present disclosure.

### DETAILED DESCRIPTION OF THE EMBODIMENTS

Hereinafter, embodiments of the present disclosure will be described with reference to the accompanying drawings. In the specification, when a certain component (or an area, a layer, a portion, etc.) is described as “on,” “over,” “above,” “connected,” or “coupled to” another component, it means that the certain component can be directly connected/coupled to another component or still one or more other components can be disposed therebetween. Further, the term “can” fully encompasses all the meanings and coverages of the term “may.”

The same reference numerals indicate the same components. In addition, in the drawings, thicknesses, proportions, and dimensions of components are exaggerated for effective description of technical contents. The term “and/or” includes all one or more combinations that can be defined by the associated configurations.

Terms such as “first,” “second,” and the like can be used to describe various components, but the components are not limited by the terms. The terms are used only for the purpose of distinguishing one component from another. For example, a first component can be referred to as a second component, and similarly, the second component can also be referred to as the first component without departing from the scopes of various embodiments of the present disclosure. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that terms such as “includes” or “has” are intended to specify the presence of features, numbers, steps, operations, components, parts, or a combination thereof described in the disclosure and does not preclude the presence or addition possibility of one or more other features, numbers, steps, operations, components, parts, or combinations thereof in advance.

All the components of each display device/apparatus according to all embodiments of the present disclosure are operatively coupled and configured.

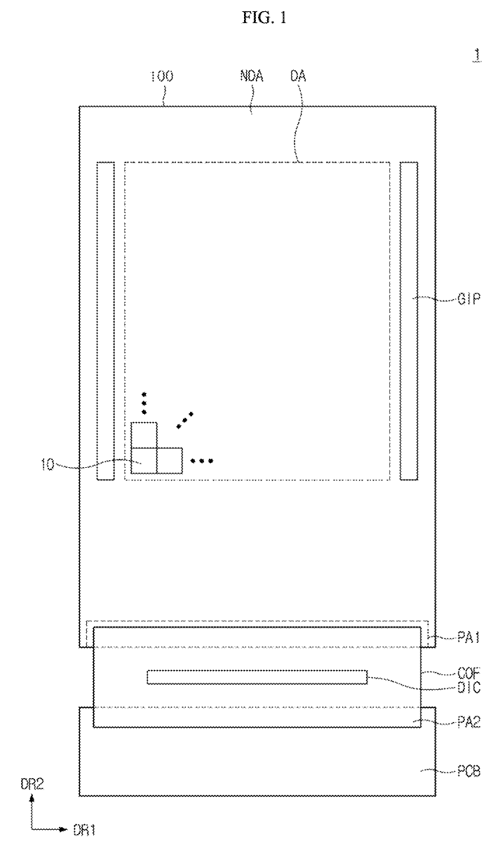

FIG. 1 is a plan view of a display device according to one embodiment of the present disclosure.

Referring to FIG. 1, a display device 1 according to one embodiment of the present disclosure can include a substrate 100, and the substrate 100 can include a display area DA (or active area) including a plurality of pixels 10, and a non-display area NDA (or non-active area) around the display area DA. The non-display area NDA can surround the display area DA and does not include the pixel 10, and thus may not generate an image, but various embodiments of the present disclosure are not limited thereto. The non-display area NDA can include a first pad area PA1 positioned on the other side of the display area DA in a second direction DR2.

A gate driver GIP can be disposed in the non-display area NDA at one side and the other side of the display area DA in a first direction DR1. The gate driver GIP can be formed in the form of an integrated circuit on the substrate 100, but is not limited thereto, and can be formed in the form of a driving chip. In FIG. 1, the gate driver GIP is illustrated as being disposed on each of left and right sides (e.g., one side and the other side in the first direction DR1) of the display area DA, but is not limited thereto, and can be disposed on only one of the left side (e.g., one side or the other side in the first direction DR1) or the right side (e.g., one side or the other side in the second direction DR2) of the display area DA.

A connection film COF can be attached to the first pad area PA1. A data driver DIC can be disposed on the connection film COF. The data driver DIC can be provided in the form of a driving chip, but various embodiments of the present disclosure are not limited thereto. One end of the connection film COF can be connected to the first pad area PA1, and the other end can include a second pad area PA2. A printed circuit board PCB can be connected to the second pad area PA2 of the connection film COF.

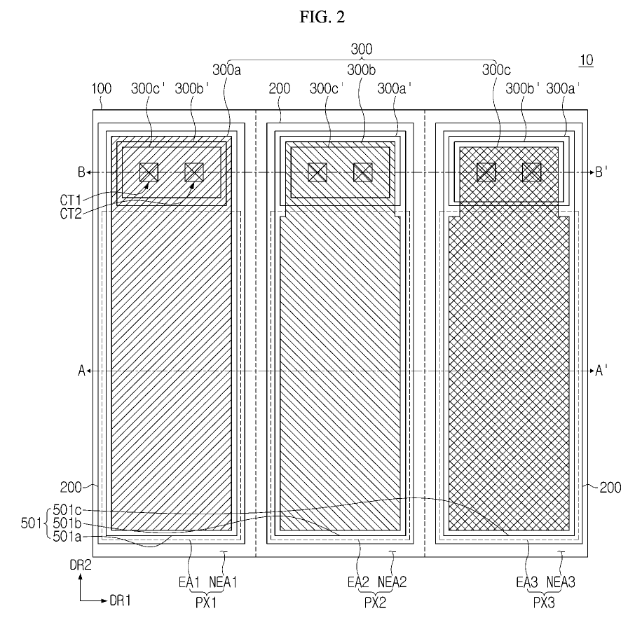

FIG. 2 is a plan view of a pixel of FIG. 1 according to an example of the present disclosure. Each pixel in the display device of FIG. 1 can have the configuration of FIG. 2.

Referring to FIG. 2, the pixel 10 can include a plurality of sub-pixels PX1, PX2, and PX3. The plurality of sub-pixels PX1, PX2, and PX3 can include a first sub-pixel PX1, a second sub-pixel PX2, and a third sub-pixel PX3. Since the first sub-pixel PX1, the second sub-pixel PX2, and the third sub-pixel PX3 can be arranged sequentially, the second sub-pixel PX2 can be disposed adjacent to one side (e.g., the right side) of the first sub-pixel PX1, and the third sub-pixel PX3 can be disposed adjacent to one side (e.g., the right side) of the second sub-pixel PX2.

Throughout the present disclosure, when two sub-pixels are disposed adjacent to each other, it should be understood that no other sub-pixels are disposed between the two sub-pixels.

The first sub-pixel PX1 can be provided to emit red (R) light, the second sub-pixel PX2 can be provided to emit green (G) light, and the third sub-pixel PX3 can be provided to emit blue (B) light, but various embodiments of the present disclosure are not necessarily limited thereto. For example these sub-pixels can be configured to emit different combinations of colors, or more than 3 sub-pixels can constitute a pixel.

In FIG. 2, the pixel 10 is illustrated as including, for example, only three sub-pixels PX1, PX2, and PX3, but is not limited thereto, and can include four sub-pixels. When the pixel 10 includes four sub-pixels, the pixel 10 can further include a fourth sub-pixel provided to emit white (W) light.

The first to third sub-pixels PX1, PX2, and PX3 can have the same size. For example, the first to third sub-pixels PX1, PX2, and PX3 can have the same width and the same height. Here, the width can refer to a horizontal direction (first direction DR1) based on FIG. 2, and the height can refer to a direction (second direction DR2) perpendicular to the width based on FIG. 2, but various embodiments of the present disclosure are not limited thereto.

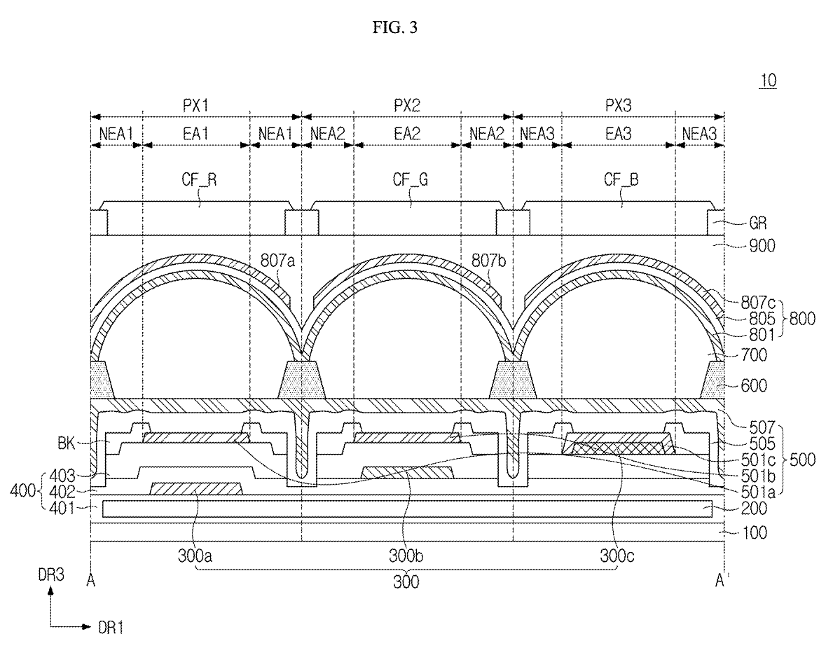

The sub-pixels PX1, PX2, and PX3 can include light-emitting areas EA1, EA2, and EA3 and non-light-emitting areas NEA1, NEA2, and NEA3, respectively. The first sub-pixel PX1 can include a first light-emitting area EA1 and a first non-light-emitting area NEA1 surrounding the first light-emitting area EA1, the second sub-pixel PX2 can include a second light-emitting area EA2 and a second non-light-emitting area NEA2 surrounding the second light-emitting area EA2, and the third sub-pixel PX3 can include a third light-emitting area EA3 and a third non-light-emitting area NEA3 surrounding the third light-emitting area EA3. The light-emitting areas EA1, EA2, and EA3 can be the same as areas exposed from a bank BK (see FIG. 3) of a lower first electrode 501, which will be described below.

The non-light-emitting areas NEA1, NEA2, and NEA3 can be disposed at boundaries between the sub-pixels PX1, PX2, and PX3. The non-light-emitting areas NEA1, NEA2, and NEA3 can also be disposed on upper end portions (e.g., one side in the second direction DR2) of the light-emitting areas EA1, EA2, and EA3, respectively. The non-light-emitting areas NEA1, NEA2, and NEA3 disposed on the upper end portions of the light-emitting areas EA1, EA2, and EA3, respectively, can be referred to as pad contact portions.

In each of the sub-pixels PX1, PX2, and PX3, a lower first electrode 501, a reflective electrode 300, connection electrodes 300a’, 300b’, and 300c’, and contact holes CT1 and CT2 can be disposed.

The lower first electrode 501 can include a lower 1-1 electrode 501a, a lower 1-2 electrode 501b, and a lower 1-3 electrode 501c. The lower first electrodes 501a, 501b, and 501c can be disposed in the sub-pixels PX1, PX2, and PX3, respectively. For example, the lower 1-1 electrode 501a can be disposed in the first sub-pixel PX1, the lower 1-2 electrode 501b can be disposed in the second sub-pixel PX2, and the lower 1-3 electrode 501c can be disposed in the third sub-pixel PX3.

The reflective electrode 300 can include a first reflective electrode 300a, a second reflective electrode 300b, and a third reflective electrode 300c. The reflective electrodes 300a, 300b, and 300c can be disposed in the sub-pixels PX1, PX2, and PX3, respectively. For example, the first reflective electrode 300a can be disposed in the first sub-pixel PX1, the second reflective electrode 300b can be disposed in the second sub-pixel PX2, and the third reflective electrode 300c can be disposed in the third sub-pixel PX3.

The reflective electrodes 300a, 300b, and 300c can be disposed across the light-emitting areas EA1, EA2, and EA3 and the non-light-emitting areas NEA1, NEA2, and NEA3 of the sub-pixels PX1, PX2, and PX3, respectively. For example, the reflective electrodes 300a, 300b, and 300c can be disposed in the light-emitting areas EA1, EA2, and EA3 of the sub-pixels PX1, PX2, and PX3, respectively, one ends of the reflective electrodes 300a, 300b, and 300c can extend upward (e.g., toward one side in the second direction DR2), and portions of the extended reflective electrodes 300a, 300b, and 300c can be disposed in the non-light-emitting areas NEA1, NEA2, and NEA3 of the sub-pixels PX1, PX2, and PX3, respectively. For example, the reflective electrodes 300a, 300b, and 300c can be disposed on the pad contact portions, respectively.

The connection electrodes 300a’, 300b’, and 300c’ can include a first connection electrode 300a’, a second connection electrode 300b’, and a third connection electrode 300c’. The connection electrodes 300a’, 300b’, and 300c’ can be provided as a plurality of connection electrodes. The plurality of connection electrodes 300a’, 300b’, and 300c’ can be disposed in each of the sub-pixels PX1, PX2, and PX3. The first connection electrode 300a’ can be disposed in the second sub-pixel PX2 and the third sub-pixel PX3, the second connection electrode 300b’ can be disposed in the first sub-pixel PX1 and the third sub-pixel PX3, and the third connection electrode 300c’ can be disposed in the first sub-pixel PX1 and the second sub-pixel PX2.

The connection electrodes 300a’, 300b’, and 300c’ can be disposed in the non-light-emitting areas NEA1, NEA2, and NEA3 of the sub-pixels PX1, PX2, and PX3, and more specifically, can be disposed in the pad contact portions. For example, the connection electrodes 300a’, 300b’, and 300c’ can be disposed in the non-light-emitting areas NEA1, NEA2, and NEA3 respectively positioned on one sides of the sub-pixels PX1, PX2, and PX3 in the second direction DR2.

The contact holes CT1 and CT2 can include a first contact hole CT1 and a second contact hole CT2, and the contact holes CT1 and CT2 can be provided as a plurality of contact holes. The first contact hole CT1 can be disposed in the first sub-pixel PX1, the second sub-pixel PX2, and the third sub-pixel PX3, and the second contact hole CT2 can be disposed in the first sub-pixel PX1, the second sub-pixel PX2, and the third sub-pixel PX3.

The contact holes CT1 and CT2 can be disposed in the non-light-emitting areas NEA1, NEA2, and NEA3 of the sub-pixels PX1, PX2, and PX3, and more specifically, can be disposed in the pad contact portions. For example, the contact holes CT1 and CT2 can be disposed in each of the non-light-emitting areas NEA1, NEA2, and NEA3 respectively positioned on the one sides of the sub-pixels PX1, PX2, and PX3 in the second direction DR2.

The first contact hole CT1 and the second contact hole CT2 disposed in each of the sub-pixels PX1, PX2, and PX3 can be disposed in parallel in the first direction DR1, but various embodiments of the present disclosure are not limited thereto.

FIG. 3 is a cross-sectional view along line A-A’ in FIG. 2 according to an example of the present disclosure.

Referring to FIG. 3, the pixel 10 of the display device 1 according to one embodiment of the present disclosure can include the substrate 100, a circuit part 200, a reflective electrode 300, an insulating layer 400, a first organic light-emitting element 500, the bank BK, an auxiliary electrode 600, a lens 700, a second organic light-emitting element 800, an encapsulation layer 900, a grid part GR, and color filters CF_R, CF_G, and CF_B.

The plurality of sub-pixels PX1, PX2, and PX3 can be formed on the substrate 100, and the plurality of sub-pixels PX1, PX2, and PX3 can form one pixel 10. A plurality of pixels 10 can be formed on the substrate 100. On the substrate 100, the first sub-pixel PX1 can emit red (R) light, the second sub-pixel PX2 can emit green (G) light, and the third sub-pixel PX3 can emit blue (B) light.

The substrate 100 can be a plastic film, a glass substrate, or a semiconductor substrate, such as silicon. The substrate 100 can be made of a transparent material or an opaque material. Since the display device 1 according to one embodiment of the present disclosure is configured in a so-called top emission type in which the emitted light is emitted upward (e.g., toward one side in a third direction DR3), both the transparent material and the opaque material can be used as a material for the substrate 100. The color filters CF_R, CF_G, and CF_B can be provided on upper portions of the first to third sub-pixels PX1, PX2, and PX3 from which the light is emitted, respectively, to transmit light of the RGB colors.

The circuit part 200 can be disposed on the substrate 100. The circuit part 200 can be disposed in each of the sub-pixels PX1, PX2, and PX3. The circuit part 200 can include a complementary metal-oxide-semiconductor (CMOS) circuit or at least one thin-film transistor, but various embodiments of the present disclosure are not limited thereto. The circuit part 200 can include a thin-film transistor, various signal lines, capacitors, etc. The signal lines can include a gate line, a data line, a power line, and a reference line, and the thin-film transistor can include a switching thin-film transistor, a driving thin-film transistor, and a sensing thin-film transistor.

The switching thin-film transistor can be switched according to a gate signal supplied to the gate line to supply a data voltage supplied from the data line to the driving thin-film transistor.

The driving thin-film transistor can be switched according to a data voltage supplied from the switching thin-film transistor to generate data current from power supplied from the power line and supply the data current to the reflective electrode 300.

The sensing thin-film transistor can detect a threshold voltage deviation of the driving thin-film transistor, which causes the degradation of image quality, and supply the current of the driving thin-film transistor to the reference line in response to a sensing control signal supplied from the gate line or a separate sensing line.

The capacitor can maintain the data voltage supplied to the driving thin-film transistor for one frame and can be connected to each of a gate terminal and a source terminal of the driving thin-film transistor.

The thin-film transistor can be disposed in each of the sub-pixels PX1, PX2, and PX3. The thin-film transistor can include a first thin-film transistor disposed in the first sub-pixel PX1, a second thin-film transistor disposed in the second sub-pixel PX2, and a third thin-film transistor disposed in the third sub-pixel PX3. The first thin-film transistor can be connected to the first reflective electrode 300a disposed on the first sub-pixel PX1 and can apply a driving voltage to emit light of a color corresponding to the first sub-pixel PX1. The second thin-film transistor can be connected to the second reflective electrode 300b disposed on the second sub-pixel PX2 and can apply a driving voltage to emit light of a color corresponding to the second sub-pixel PX2. The third thin-film transistor can be connected to the third reflective electrode 300c disposed on the third sub-pixel PX3 and can apply a driving voltage to emit light of a color corresponding to the third sub-pixel PX3. The first thin-film transistor, the second thin-film transistor, and the third thin-film transistor can be positioned in the same circuit part 200, but various embodiments of the present disclosure are not limited thereto.

Each of the first sub-pixel PX1, the second sub-pixel PX2, and the third sub-pixel PX3 uses the thin-film transistor to supply a predetermined current to a light-emitting layer according to a data voltage of the data line when receiving a gate signal from the gate line. Accordingly, the light-emitting layer of each of the first sub-pixel PX1, the second sub-pixel PX2, and the third sub-pixel PX3 can emit light with a predetermined brightness according to the predetermined current.

The reflective electrode 300 can be disposed on the circuit part 200. The reflective electrode 300 can include the first reflective electrode 300a, the second reflective electrode 300b, and the third reflective electrode 300c. The first reflective electrode 300a can be disposed in the first sub-pixel PX1, the second reflective electrode 300b can be disposed in the second sub-pixel PX2, and the third reflective electrode 300c can be disposed in the third sub-pixel PX3. The reflective electrodes 300a, 300b, and 300c can be disposed in the light-emitting areas EA1, EA2, and EA3 of the sub-pixels PX1, PX2, and PX3, respectively. However, various embodiments of the present disclosure are not limited thereto, and for example, the reflective electrodes 300a, 300b, and 300c can extend in the first direction DR1 and can be disposed across the light-emitting areas EA1, EA2, and EA3 and the non-light-emitting areas NEA1, NEA2, and NEA3. The reflective electrodes 300a, 300b, and 300c can be disposed in different layers.

The reflective electrodes 300a, 300b, and 300c can include a reflective material for reflecting light. For example, the reflective material can be a metal, but is not necessarily limited thereto, and can be other materials as long as it can reflect light. For example, the reflective material can include aluminum (Al) or silver (Ag), but various embodiments of the present disclosure are not limited thereto.

Since the reflective electrode 300 is disposed at a position relatively lower than (e.g., on the other side in the third direction DR3) that of a first common light-emitting layer 505 that emits light, the reflective electrode 300 can reflect light emitted from the first common light-emitting layer 505 upward (e.g., toward one side in the third direction DR3). Here, the term “upward” can refer to a direction in which a user can perceive light, for example, a side on which the color filters CF_R, CF_G, and CF_B are disposed. Accordingly, the optical efficiencies of the first sub-pixel PX1, the second sub-pixel PX2, and the third sub-pixel PX3 can be improved compared to a case in which no reflective electrode 300 is provided, thereby allowing the user to perceive an image with high luminance, for example, a clearer image, due to the improved optical efficiency.

In the light-emitting areas EA1, EA2, and EA3, separation distances between each of the reflective electrodes 300a, 300b, and 300c and a lower second electrode 507 can be different. The separation distance between the first reflective electrode 300a and the lower second electrode 507 can be greater than the separation distance between the second reflective electrode 300b and the lower second electrode 507, and the separation distance between the second reflective electrode 300b and the lower second electrode 507 can be greater than the separation distance between the third reflective electrode 300c and the lower second electrode 507. Accordingly, the separation distance between the first reflective electrode 300a and the lower second electrode 507 can be the largest, followed by the separation distance between the second reflective electrode 300b and the lower second electrode 507, and finally, the separation distance between the third reflective electrode 300c and the lower second electrode 507 can be the smallest.

The display device 1 (see FIG. 1) can further improve light extraction efficiency using microcavity characteristics by including the reflective electrodes 300a, 300b, and 300c having different separation distances from the lower second electrode 507 in each of the sub-pixels PX1, PX2, and PX3.

The microcavity characteristics refer to a phenomenon in which light is amplified due to constructive interference when the distances between the reflective electrodes 300a, 300b, and 300c and the lower second electrode 507 correspond to an integer multiple of half the wavelength (λ/2) of the light emitted from the sub-pixels PX1, PX2, and PX3, and in which repeated reflection and re-reflection between the reflective electrodes 300a, 300b, and 300c and the lower second electrode 507 further increases the degree of light amplification, thereby enhancing light extraction efficiency.

Accordingly, the light extraction efficiency of red light can be improved in the first sub-pixel PX1, the light extraction efficiency of green light can be improved in the second sub-pixel PX2, and the light extraction efficiency of blue light can be improved in the third sub-pixel PX3.

The circuit part 200 and the reflective electrode 300 can be insulated by the insulating layer 400. The insulating layer 400 can include a first insulating layer 401, a second insulating layer 402, and a third insulating layer 403. The insulating layer 400 can be made of an inorganic insulation material, but is not necessarily limited thereto, and can be made of an organic insulation material. For example, the insulating layer 400 can be made of an inorganic material, such as silicon nitride (SiNₓ), silicon oxide (SiOₓ), aluminum oxide (Al₂O₃), etc., but various embodiments of the present disclosure are not limited thereto.

The first insulating layer 401 can protect transistors and lines disposed in the circuit part 200. The first reflective electrode 300a can be disposed between the first insulating layer 401 and the second insulating layer 402, the second reflective electrode 300b can be disposed between the second insulating layer 402 and the third insulating layer 403, and the third reflective electrode 300c can be disposed on the third insulating layer 403.

A trench can be formed in the insulating layer 400. For example, the trench can be formed in the non-light-emitting areas NEA1, NEA2, and NEA3. The trench can be formed by passing through portions of the third insulating layer 403 and the second insulating layer 402, but various embodiments of the present disclosure are not limited thereto. In the display device 1 (see FIG. 1) according to one embodiment, since the trench is formed between adjacent sub-pixels PX1, PX2, and PX3, a lateral leakage current (LLC) between the adjacent sub-pixels PX1, PX2, and PX3, which is caused by the first common light-emitting layer 505, can be reduced.

The first organic light-emitting element 500 can be disposed on the reflective electrode 300. The first organic light-emitting element 500 can include the lower first electrode 501, the lower second electrode 507, and the first common light-emitting layer 505 interposed between the lower first electrode 501 and the lower second electrode 507.

The lower first electrode 501 can be disposed on the third insulating layer 403. The lower first electrode 501 can include the lower 1-1 electrode 501a, the lower 1-2 electrode 501b, and the lower 1-3 electrode 501c. The lower 1-1 electrode 501a can be disposed in the first light-emitting area EA1 of the first sub-pixel PX1, the lower 1-2 electrode 501b can be disposed in the second light-emitting area EA2 of the second sub-pixel PX2, and the lower 1-3 electrode 501c can be disposed in the third light-emitting area EA3 of the third sub-pixel PX3. In the third light-emitting area EA3 of the third sub-pixel PX3, the lower 1-3 electrode 501c can be disposed directly on the third reflective electrode 300c.

The lower first electrode 501 can include a material with high light transmittance. For example, the lower first electrode 501 can include ITO, IZO, or TiN, but various embodiments of the present disclosure are not limited thereto, and any transparent electrode with high light transmittance can be used for the lower first electrode 501. The lower first electrode 501 can function as an anode of the display device 1 (see FIG. 1).

The bank BK can be disposed on the lower first electrode 501. The bank BK can be made of an inorganic material, such as silicon nitride (SiNₓ), silicon oxide (SiOₓ), aluminum oxide (Al₂O₃), etc., but various embodiments of the present disclosure are not limited thereto. The bank BK can be disposed on each of the non-light-emitting areas NEA1, NEA2, and NEA3.

In the light-emitting areas EA1, EA2, and EA3, the bank BK can expose the upper surface of each of the lower first electrodes 501a, 501b, and 501c to define each of the light-emitting areas EA1, EA2, and EA3. The bank BK can be in contact with the upper surface of each of the lower first electrodes 501a, 501b, and 501c and side surfaces of each of the lower first electrodes 501a, 501b, and 501c.

The first common light-emitting layer 505 can be disposed on the lower first electrodes 501a, 501b, and 501c and the banks BK. The first common light-emitting layer 505 can be in contact with the upper surfaces of the lower first electrodes 501a, 501b, and 501c. The first common light-emitting layer 505 can be in direct contact with the upper surfaces of the first electrodes 501a, 501b, and 501c, the upper surface and side surfaces of the banks BK, and the insulating layer 400. The first common light-emitting layer 505 can also be disposed to extend to the trench. The first common light-emitting layer 505 can be formed as a common layer across the first to third sub-pixels PX1, PX2, and PX3.

The first common light-emitting layer 505 can emit white (W) light. To this end, the first common light-emitting layer 505 can include a plurality of stacks that emit light of different colors. Specifically, the first common light-emitting layer 505 can include a first stack, a second stack, and a charge generation layer CGL interposed between the first stack and the second stack.

For example, the first common light-emitting layer 505 can emit white light by having a two-stack structure including a blue light-emitting layer, a yellow-green light-emitting layer, and a charge generation layer or a three-stack structure including a blue light-emitting layer, a green light-emitting layer, a red light-emitting layer, and a charge generation layer, but is not necessarily limited thereto, and can be formed of multiple layers exceeding 3 stacks as long as it can emit white light.

The lower second electrode 507 can be disposed on the first common light-emitting layer 505. The lower second electrode 507 can function as a cathode of the display device 1 (see FIG. 1). Like the first common light-emitting layer 505, the lower second electrode 507 can be disposed in each of the sub-pixels PX1, PX2, and PX3 and between the sub-pixels PX1, PX2, and PX3. The lower second electrode 507 can be formed to function as a common layer across the first to third sub-pixels PX1, PX2, and PX3.

The lower second electrode 507 can be formed of a translucent electrode and can include, for example, silver (Ag) or magnesium (Mg), but various embodiments of the present disclosure are not limited thereto, and any translucent electrode can be used for the lower second electrode 507.

Since the lower second electrode 507 is formed of the translucent electrode, a microcavity effect can be achieved in each of the first to third sub-pixels PX1, PX2, and PX3. The reflection and re-reflection of light can be repeated between the lower second electrode 507 and each of the reflective electrodes 300a, 300b, and 300c, thereby achieving the microcavity effect and improving light extraction efficiency.

The auxiliary electrode 600 can be disposed on the first organic light-emitting element 500. The auxiliary electrode 600 can be disposed between the sub-pixels PX1, PX2, and PX3. For example, the auxiliary electrodes 600 can be disposed at the boundaries between the sub-pixels PX1, PX2, and PX3 in the non-light-emitting areas NEA1, NEA2, and NEA3 of the sub-pixels PX1, PX2, and PX3.

The auxiliary electrode 600 can include a conductive material. For example, the auxiliary electrode 600 can include silver (Ag) or an alloy thereof. The auxiliary electrode 600 can electrically connect the lower second electrode 507 of the first organic light-emitting element 500 to an upper second electrode 801 of the second organic light-emitting element 800.

The auxiliary electrode 600 can include a material that reflects light. Accordingly, the light emitted from the first common light-emitting layer 505 can be reflected by the auxiliary electrode 600, and the optical path can be changed.

A lens 700 can be disposed between the auxiliary electrodes 600. The lens 700 can be disposed in each of the sub-pixels PX1, PX2, and PX3. The lens 700 can have a convex shape upward (e.g., toward one side in the third direction DR3). Accordingly, thicknesses of the lenses 700 in the light-emitting areas EA1, EA2, and EA3 of the sub-pixels PX1, PX2, and PX3 can be greater than those of the lenses 700 in the non-light-emitting areas NEA1, NEA2, and NEA3.

The second organic light-emitting element 800 can be disposed on the lens 700. The second organic light-emitting element 800 can include an upper second electrode 801, a second common light-emitting layer 805, and an upper first electrode 807.

The upper second electrode 801 can function as a cathode of the display device 1 (see FIG. 1). The upper second electrode 801 can be disposed in a convex shape upward along an upper surface of the lens 700 (e.g., one side in the third direction DR3) and can also be disposed on the auxiliary electrode 600. The upper second electrode 801 can be disposed on each of the sub-pixels PX1, PX2, and PX3 and between the sub-pixels PX1, PX2, and PX3.

The upper second electrode 801 can be formed of a translucent electrode and can include, for example, silver (Ag) or magnesium (Mg), but various embodiments of the present disclosure are not limited thereto, and any translucent electrode can be used for the upper second electrode 801.

Since the upper second electrode 801 is formed of the translucent electrode, a microcavity effect can be achieved in each of the first to third sub-pixels PX1, PX2, and PX3. The reflection and re-reflection of light can be repeated between the upper second electrode 801 and the lower second electrode 507, thereby achieving the microcavity effect and improving light extraction efficiency.

The second common light-emitting layer 805 is formed on the upper second electrode 801. The second common light-emitting layer 805 can be in direct contact with an upper surface of the upper second electrode 801. Since the upper second electrode 801 is disposed in a convex shape upward (e.g., toward one side in the third direction DR3), the second common light-emitting layer 805 can also be disposed in a convex shape upward (e.g., toward one side in the third direction DR3). Since the second common light-emitting layer 805 can be disposed in each of the sub-pixels PX1, PX2, and PX3 and between the sub-pixels PX1, PX2, and PX3, the second common light-emitting layer 805 can be disposed across the sub-pixels PX1, PX2, and PX3.

The second common light-emitting layer 805 can emit white (W) light. To this end, the second common light-emitting layer 805 can include a plurality of stacks that emit light of different colors. Specifically, the second common light-emitting layer 805 can include a first stack, a second stack, and a charge generation layer CGL interposed between the first stack and the second stack.

The second common light-emitting layer 805 can emit light having a specific wavelength. For example, the second common light-emitting layer 805 can emit light of a first wavelength (e.g., red (R) light), a second wavelength (e.g., green (G) light), or a third wavelength (e.g., blue (B) light). Accordingly, the second common light-emitting layer 805 can have a function of supplementing an insufficient color component in the pixel 10.

The upper first electrode 807 can be disposed on the second common light-emitting layer 805, and the upper first electrode 807 can be in direct contact with the second common light-emitting layer 805. The upper first electrode 807 can include an upper 1-1 electrode 807a, an upper 1-2 electrode 807b, and an upper 1-3 electrode 807c. The upper 1-1 electrode 807a can be disposed in the first light-emitting area EA1 and the first non-light-emitting area NEA1 of the first sub-pixel PX1, the upper 1-2 electrode 807b can be disposed in the second light-emitting area EA2 and the second non-light-emitting area NEA2 of the second sub-pixel PX2, and the upper 1-3 electrode 807c can be disposed in the third light-emitting area EA3 and the third non-light-emitting area NEA3 of the third sub-pixel PX3.

As the second common light-emitting layer 805 is disposed in a convex shape upward (e.g., toward one side in the third direction DR3), each of the upper 1-1 electrodes 807a, 807b, and 807c can also be disposed in a convex shape upward (e.g., toward one side in the third direction DR3). The encapsulation layer 900 can be disposed between the upper first electrodes 807a, 807b, and 807c. Accordingly, the upper first electrodes 807a, 807b, and 807c can be insulated.

The upper first electrode 807 can include a material with high light transmittance. For example, the upper first electrode 807 can include ITO, IZO, or TiN, but various embodiments of the present disclosure are not limited thereto, and any transparent electrode with high light transmittance can be used for the upper first electrode 807. The upper first electrode 807 can function as an anode of the display device 1 (see FIG. 1).

The encapsulation layer 900 can be disposed on the upper first electrode 807. The encapsulation layer 900 can be disposed on the upper first electrode 807 and the second common light-emitting layer 805. Since the upper first electrode 807 and the second common light-emitting layer 805 are disposed in a convex shape upward (e.g., toward one side in the third direction DR3) in each of the sub-pixels PX1, PX2, and PX3, a step due to thickness can occur. The encapsulation layer 900 can also be disposed between the upper first electrodes 807a, 807b, and 807c in the non-light-emitting areas NEA1, NEA2, and NEA3 of the sub-pixels PX1, PX2, and PX3, thereby eliminating such a step.

The encapsulation layer 900 can prevent external moisture from penetrating the second common light-emitting layer 805. The encapsulation layer 900 can be made of an inorganic insulation material or formed in a structure in which an inorganic insulation material and an organic insulation material are alternately stacked, but is not necessarily limited thereto.

In the pixel 10 according to one embodiment of the present disclosure, the encapsulation layer 900 can be disposed on the upper first electrode 807, and the upper first electrode 807 can be formed of a film made of a translucent material, such as ITO, IZO, TiN, etc. Accordingly, a thickness of the encapsulation layer 900 can be reduced. When the thickness of the encapsulation layer 900 is reduced, color mixing between adjacent pixels 10 can be prevented.

The color filters CF_R, CF_G, and CF_B can be disposed on the encapsulation layer 900. The color filters CF_R, CF_G, and CF_B can include a first color filter CF_R provided in the first sub-pixel PX1, a second color filter CF_G provided in the second sub-pixel PX2, and a third color filter CF_B provided in the third sub-pixel PX3.

The color filters CF_R, CF_G, and CF_B can block specific colors from the light emitted from the second common light-emitting layers 805 and the first common light-emitting layers 505 of the sub-pixels PX1, PX2, and PX3. The first color filter CF_R disposed in the first sub-pixel PX1 can block light of colors other than red (R) light. The second color filter CF_G disposed in the second sub-pixel PX2 can block light of colors other than green (G) light. The third color filter CF_B disposed in the third sub-pixel PX3 can block light of colors other than blue (B) light. However, various embodiments of the present disclosure are not limited thereto.

The grid parts GR can be disposed on the encapsulation layer 900 and disposed in the non-light-emitting areas NEA1, NEA2, and NEA3 of the sub-pixels PX1, PX2, and PX3. The grid parts GR can be disposed between the sub-pixels PX1, PX2, and PX3. The grid parts GR can be disposed between adjacent color filters CF_R, CF_G, and CF_B, thereby reducing signal interference.

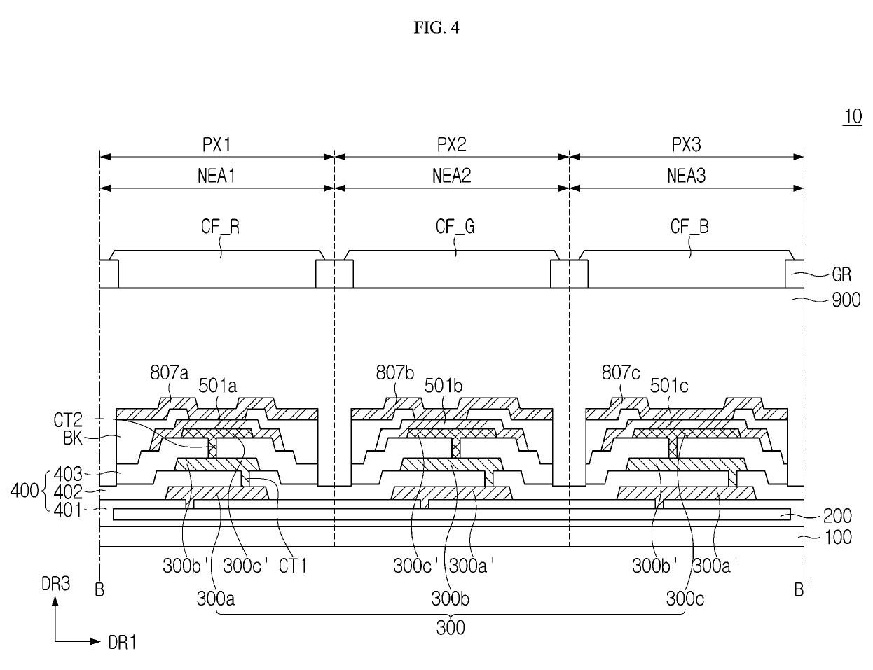

FIG. 4 is a cross-sectional view along line B-B’ in FIG. 2 according to an example of the present disclosure.

For example, FIG. 4 is a cross-sectional view illustrating an electrical connection relationship in the non-light-emitting area NEA of the pixel 10 according to one embodiment of the present disclosure.

In the first non-light-emitting area NEA1 of the first sub-pixel PX1, the first reflective electrode 300a can be disposed between the first insulating layer 401 and the second insulating layer 402, in the second non-light-emitting area NEA2 of the second sub-pixel PX2, the second reflective electrode 300b can be disposed between the second insulating layer 402 and the third insulating layer 403, and in the third non-light-emitting area NEA3 of the third sub-pixel PX3, the third reflective electrode 300c can be disposed between the third insulating layer 403 and the lower 1-3 electrode 501c.

The connection electrodes 300a’, 300b’, and 300c’ can be disposed between the insulating layers 400. The connection electrodes 300a’, 300b’, and 300c’ can include the first connection electrode 300a’, the second connection electrode 300b’, and the third connection electrode 300c’.

The first connection electrode 300a’ can be disposed between the first insulating layer 401 and the second insulating layer 402 in the second sub-pixel PX2 and the third sub-pixel PX3. The second connection electrode 300b’ can be disposed between the second insulating layer 402 and the third insulating layer 403 in the first sub-pixel PX1 and the third sub-pixel PX3. The third connection electrode 300c’ can be disposed between the third insulating layer 403 and the first insulating layer 401 in the first sub-pixel PX1 and the second sub-pixel PX2. The connection electrodes 300a’, 300b’, and 300c’ can be disposed in the non-light-emitting areas NEA1, NEA2, and NEA3 of the sub-pixels PX1, PX2, and PX3, respectively.

In the first sub-pixel PX1, the circuit part 200 can be electrically connected to the first reflective electrode 300a, the first reflective electrode 300a can be electrically connected to the second connection electrode 300b’ through the first contact hole CT1, and the second connection electrode 300b’ can be electrically connected to the third connection electrode 300c’ through the second contact hole CT2.

In the second sub-pixel PX2, the circuit part 200 can be electrically connected to the first connection electrode 300a’, the first connection electrode 300a’ can be electrically connected to the second reflective electrode 300b through the first contact hole CT1, and the second reflective electrode 300b can be electrically connected to the third connection electrode 300c’ through the second contact hole CT2.

In the third sub-pixel PX3, the circuit part 200 can be electrically connected to the first connection electrode 300a’, the first connection electrode 300a’ can be electrically connected to the second connection electrode 300b’ through the first contact hole CT1, and the second connection electrode 300b’ can be electrically connected to the third reflective electrode 300c through the second contact hole CT2.

The first reflective electrode 300a and the first connection electrode 300a’ can be disposed on the same layer and can include the same material. The second reflective electrode 300b and the second connection electrode 300b’ can be disposed on the same layer and can include the same material. The third reflective electrode 300c and the third connection electrode 300c’ can be disposed on the same layer and can include the same material.

In the non-light-emitting areas NEA1, NEA2, and NEA3 of the first to third sub-pixels PX1, PX2, and PX3, the lower first electrodes 501a, 501b, and 501c can be directly disposed on the third connection electrode 300c’ and the third reflective electrode 300c. Accordingly, the lower first electrodes 501a, 501b, and 501c can be electrically connected to the circuit part 200 in the non-light-emitting areas NEA1, NEA2, and NEA3, respectively.

In the non-light-emitting areas NEA1, NEA2, and NEA3 of the first to third sub-pixels PX1, PX2, and PX3, the upper first electrodes 807a, 807b, and 807c can be directly disposed on the lower first electrode 501a, 501b, and 501c and the banks BK, respectively. Accordingly, the upper first electrodes 807a, 807b, and 807c can be electrically connected to the circuit part 200 in the non-light-emitting areas NEA1, NEA2, and NEA3, respectively.

Since the remaining parts have been described above in FIG. 3, the detailed descriptions thereof will be omitted below.

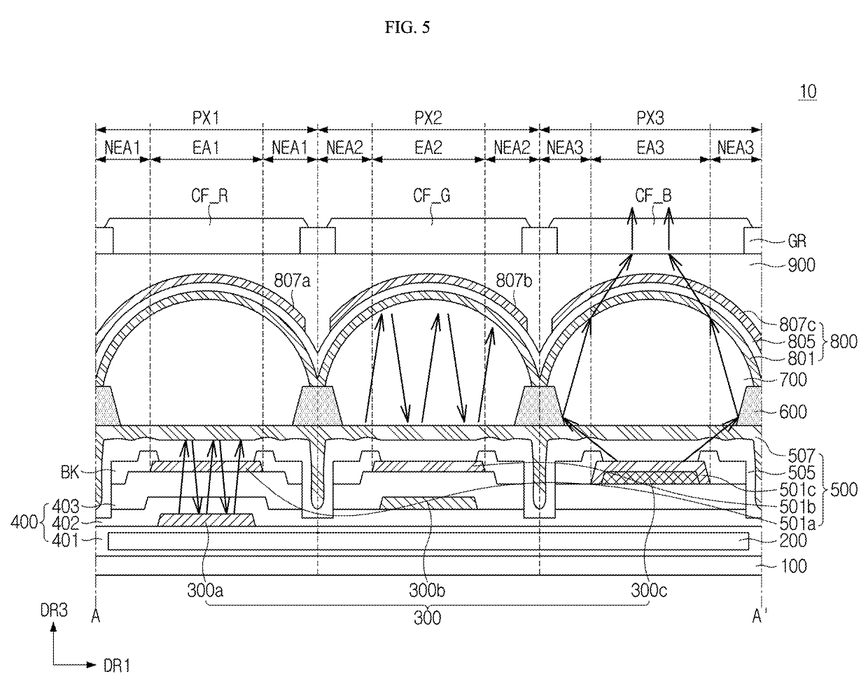

FIG. 5 is a schematic view illustrating an optical path in FIG. 2 according to an example of the present disclosure.

Referring to FIG. 5, since the reflective electrode 300 can include a reflective material for reflecting light and the lower second electrode 507 can include a translucent electrode, both the reflective electrode 300 and the lower second electrode 507 can reflect light. Accordingly, the light emitted from the first common light-emitting layer 505 of the sub-pixels PX1, PX2, and PX3 can be repeatedly reflected and re-reflected between each of the reflective electrodes 300a, 300b, and 300c and the lower second electrode 507, thereby achieving the microcavity effect.

The light emitted from the first common light-emitting layer 505 can also undergo a resonance process between the upper second electrode 801 and the lower second electrode 507. Since both the upper second electrode 801 and the lower second electrode 507 can include translucent electrodes, light can be repeatedly reflected and re-reflected between the upper second electrode 801 and the lower second electrode 507. Accordingly, the microcavity effect of the light can be achieved from the lens 700 disposed between the upper second electrode 801 and the lower second electrode 507, and light extraction efficiency can be improved.

Since the auxiliary electrode 600 can include a reflective material for reflecting light, the light emitted from the first common light-emitting layer 505 can also be reflected by the auxiliary electrode 600. The path of the reflected light can be changed toward the center of the lens 700. The reflected light can pass through the lens 700 and can be condensed toward the center of each of the sub-pixels PX1, PX2, and PX3, thereby improving optical efficiency. As the optical efficiency improves, the luminance of the display device 1 (see FIG. 1) according to one embodiment of the present disclosure can increase.

The light amplified through the microcavity effect and the light reflected by the auxiliary electrode 600 can be reflected upward (e.g., toward one side in the third direction DR3) and discharged to the outside. Here, the term “upward” can refer to a direction in which a user can perceive light, for example, a side on which the encapsulation layer 900 or the color filters CF_R, CF_G, and CF_B are disposed.

Since the remaining parts have been described above in FIG. 3, the detailed descriptions thereof will be omitted below.

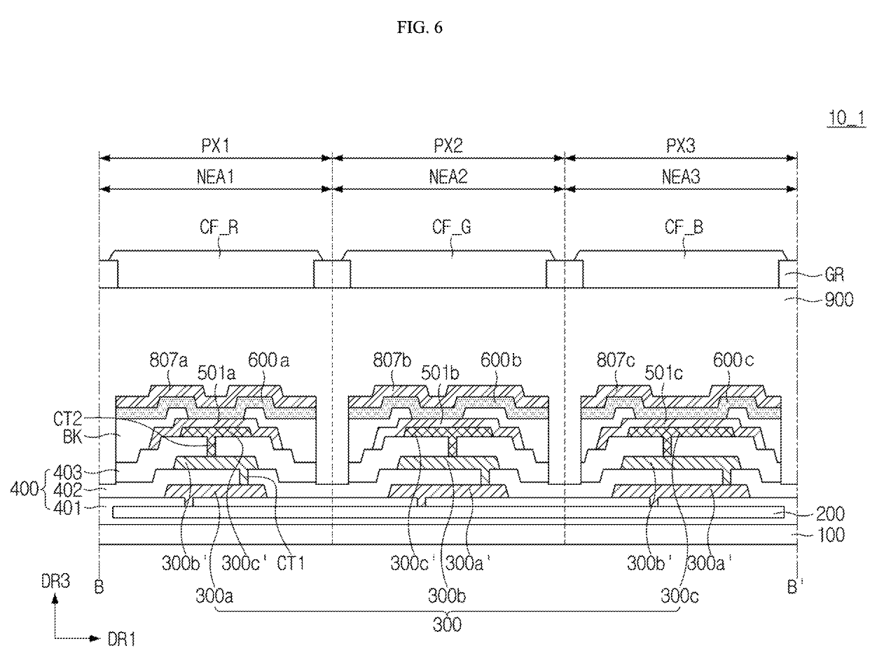

FIG. 6 is a cross-sectional view along line B-B’ of a pixel of a display device according to another embodiment of the present disclosure. For example, line B-B’ of FIG. 6 is a different example of line B-B’ of FIG. 4.

Referring to FIG. 6, a pixel 10_1 according to the present embodiment of the present disclosure differs from the pixel 10 according to FIG. 4 in that it further includes the auxiliary electrode 600 between the lower first electrode 501 and the upper first electrode 807.

The auxiliary electrode 600 can be disposed on the lower first electrodes 501a, 501b, and 501c and the banks BK respectively disposed in the sub-pixels PX1, PX2, and PX3. The auxiliary electrode 600 can include a first auxiliary electrode 600a disposed in the first sub-pixel PX1, a second auxiliary electrode 600b disposed in the second sub-pixel PX2, and a third auxiliary electrode 600c disposed in the third sub-pixel PX3. Since the auxiliary electrodes 600a, 600b, and 600c can be in direct contact with the lower first electrodes 501a, 501b, and 501c and the banks BK, respectively, the auxiliary electrodes 600a, 600b, and 600c can be electrically connected to the lower first electrodes 501a, 501b, and 501c, respectively. The encapsulating layer 900 can be disposed between the auxiliary electrodes 600a, 600b, and 600c, and the encapsulation layer 900 can insulate the auxiliary electrodes 600a, 600b, and 600c.

The upper first electrodes 807a, 807b, and 807c can be disposed on the auxiliary electrodes 600a, 600b, and 600c, respectively. The auxiliary electrodes 600a, 600b, and 600c and the upper first electrodes 807a, 807b, and 807c can be electrically connected, respectively. Accordingly, in the sub-pixels PX1, PX2, and PX3, the circuit part 200, the lower first electrodes 501a, 501b, and 501c, the auxiliary electrodes 600a, 600b, and 600c, and the upper first electrodes 807a, 807b, and 807c can be electrically connected, respectively.

Since the remaining parts have been described above in FIGS. 3 and 4, the detailed descriptions thereof will be omitted below.

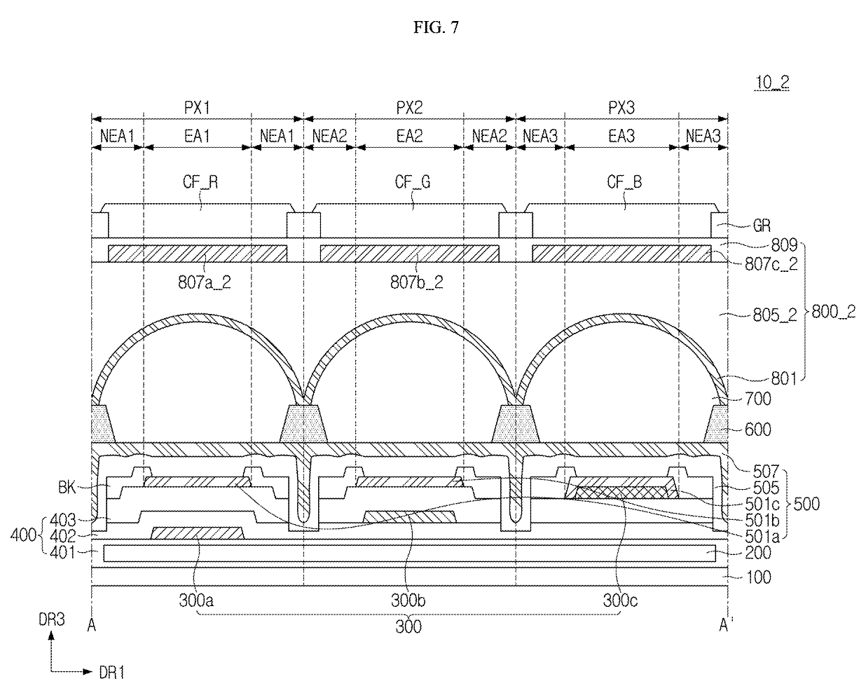

FIG. 7 is a cross-sectional view along line A-A’ of a pixel of a display device according to still another embodiment of the present disclosure. For example, line A-A’ of FIG. 7 is a different example of line A-A’ of FIG. 3.

Referring to FIG. 7, a pixel 10_2 according to the present embodiment of the present disclosure differs from the pixel 10 according to FIG. 3 in that a thickness of a second common light-emitting layer 805_2 is formed differently in each of the light-emitting area EA and the non-light-emitting area NEA.

A second organic light-emitting element 800_2 can include the upper second electrode 801, the second common light-emitting layer 805_2, an upper first electrode 807_2, and an insulating layer 809. The upper second electrode 801 can be disposed along the lens 700, and thus can be disposed in a convex shape upward (e.g., toward one side in the third direction DR3).

The second common light-emitting layer 805_2 can be disposed on the upper second electrode 801, and the second common light-emitting layer 805_2 can be formed to function as a common layer across the first to third sub-pixels PX1, PX2, and PX3. In this case, a thickness of the second common light-emitting layer 805_2 in the light-emitting areas EA1, EA2, and EA3 of the sub-pixels PX1, PX2, and PX3 can be greater than that of the second common light-emitting layer 805_2 in the non-light-emitting areas NEA1, NEA2, and NEA3. For example, the second common light-emitting layer 805_2 can be disposed to fill spaces between the upper second electrodes 801 formed to be convex upward in each of the sub-pixels PX1, PX2, and PX3. Accordingly, the lens 700 and a surface formed convexly by the upper second electrode 801 can be planarized by the second common light-emitting layer 805_2. The second common light-emitting layer 805_2 can be formed by a soluble (solution-processable) method in which a solid organic material is converted into a solution to form a film. More specifically, a thickness of a hole transport layer of the second common light-emitting layer 805_2 can be adjusted to control a step between the light-emitting area EA and the non-light-emitting area NEA.

The upper first electrode 807_2 can be disposed on the second common light-emitting layer 805_2. The upper first electrode 807_2 can include an upper 1-1 electrode 807a_2 disposed in the first sub-pixel PX, an upper 1-2 electrode 807b_2 disposed in the second sub-pixel PX2, and an upper 1-3 electrode 807c_2 disposed in the third sub-pixel PX3. The insulating layer 809 can be disposed between the upper first electrodes 807a_2, 807b_2, and 807c_2. The insulating layer 809 can insulate the upper first electrodes 807a_2, 807b_2, and 807c_2.

The insulating layer 809 can also be disposed on the upper first electrodes 807a_2, 807b_2, and 807c_2. Accordingly, the insulating layer 809 can prevent the second common light-emitting layer 805_2 from being damaged during the process of forming the color filters CF_R, CF_G, and CF_B.

Since the remaining parts have been described above in FIGS. 3 and 4, the detailed descriptions thereof will be omitted below.

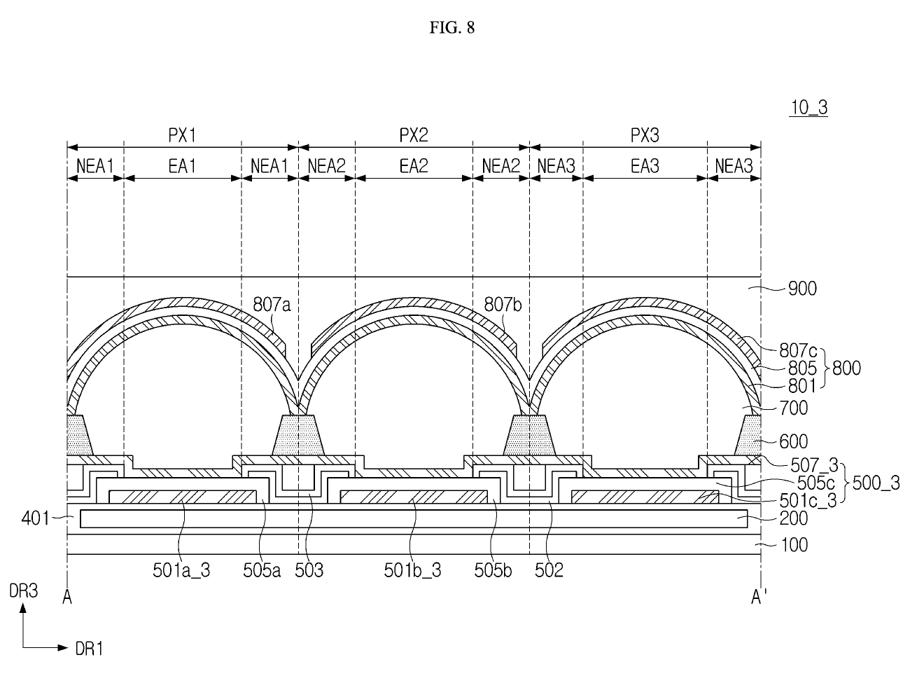

FIG. 8 is a cross-sectional view along line A-A’ of a pixel of a display device according to yet another embodiment of the present disclosure. For example, line A-A’ of FIG. 8 is a different example of line A-A’ of FIG. 3.

Referring to FIG. 8, a pixel 10_3 according to the present embodiment of the present disclosure differs from the pixel 10 according to FIG. 3 in that it has no color filter CF (see FIG. 3) and the first common light-emitting layer 505 (see FIG. 3) includes organic layers 505a, 505b, and 505c that emit red (R), green (G), or blue (B) light, respectively.

A first organic light-emitting element 500_3 can include a lower first electrode 501_3, the organic layers 505a, 505b, and 505c, a lower second electrode 507_3, a first lower insulating layer 502, and a second lower insulating layer 503.

The lower first electrode 501_3 can include a lower 1-1 electrode 501a_3 disposed in the first sub-pixel PX1, a lower 1-2 electrode 501b_3 disposed in the second sub-pixel PX2, and a lower 1-3 electrode 501c_3 disposed in the third sub-pixel PX3.

The organic layers 505a, 505b, and 505c can include a first organic layer 505a disposed in the first sub-pixel PX1, a second organic layer 505b disposed in the second sub-pixel PX2, and a third organic layer 505c disposed in the third sub-pixel PX3. The organic layers 505a, 505b, and 505c can be physically separated. The organic layers 505a, 505b, and 505c can surround upper and side surfaces of the lower first electrodes 501a_3, 501b_3, and 501c_3.

The first organic layer 505a can emit light of a fourth wavelength, and the light of the fourth wavelength can be red (R) light. The second organic layer 505b can emit light of a fifth wavelength, and the light of the fifth wavelength can be green (G) light. The third organic layer 505c can emit light of a sixth wavelength, and the light of the sixth wavelength can be blue (B) light.

The first lower insulating layer 502 can be disposed on the organic layers 505a, 505b, and 505c and the first insulating layer 401 and disposed in the non-light-emitting areas NEA1, NEA2, and NEA3 between the sub-pixels PX1, PX2, and PX3. The first lower insulating layer 502 can insulate the organic layers 505a, 505b, and 505c.

The first lower insulating layer 502 can be made of an inorganic material, such as aluminum oxide (Al₂O₃), but various embodiments of the present disclosure are not limited thereto.

The second lower insulating layer 503 can be disposed on the first lower insulating layer 502. The second lower insulating layer 503 can be disposed in the non-light-emitting areas NEA1, NEA2, and NEA3 between the sub-pixels PX1, PX2, and PX3 and between the organic layers 505a, 505b, and 505c. The second lower insulating layer 503 can eliminate steps between adjacent organic layers 505a, 505b, and 505c.

The second lower insulating layer 503 can include an organic material and a negative-type photosensitive material, but various embodiments of the present disclosure are not limited thereto.

The lower second electrode 507_3 can be disposed on the organic layers 505a, 505b, and 505c and the second lower insulating layer 503. The lower second electrode 507_3 can be formed to function as a common layer across the first to third sub-pixels PX1, PX2, and PX3.

Since the organic layers 505a, 505b, and 505c emit red (R) light, green (G) light, or blue (B) light, respectively, the color filters CF_R, CF_G, and CF_B (see FIG. 3) may not be disposed on the encapsulation layer 900. However, various embodiments of the present disclosure are not limited thereto, and the color filters CF_R, CF_G, and CF_B (see FIG. 3) can be disposed on the encapsulation layer 900 in the sub-pixels PX1, PX2, and PX3, respectively.

Since the remaining parts have been described above in FIGS. 3 and 4, the detailed descriptions thereof will be omitted below.

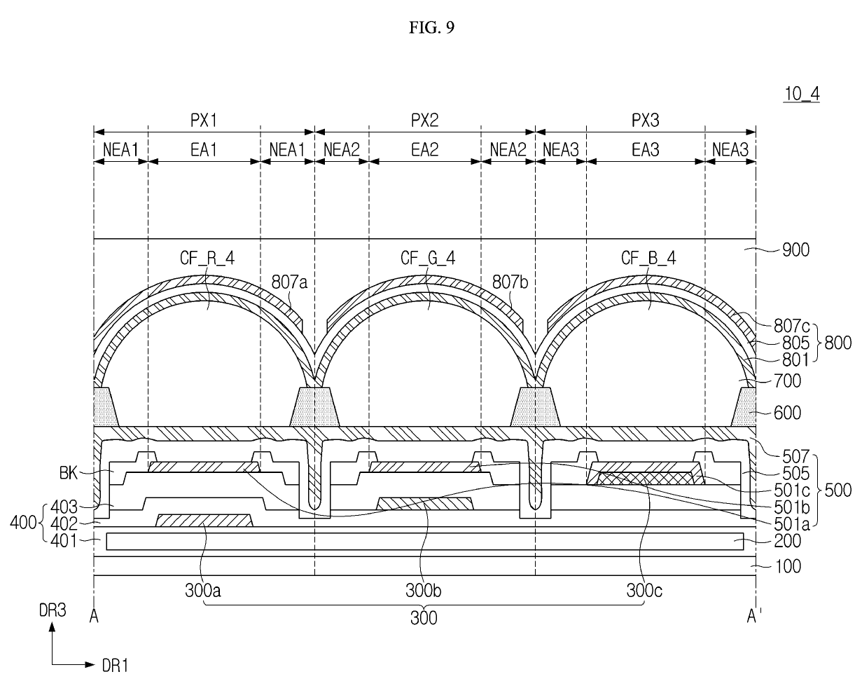

FIG. 9 is a cross-sectional view along line A-A’ of a pixel of a display device according to yet another embodiment of the present disclosure. For example, line A-A’ of FIG. 9 is a different example of line A-A’ of FIG. 3.

Referring to FIG. 9, a pixel 10_4 according to the present embodiment of the present disclosure differs from the pixel 10 according to FIG. 3 in that the color filter CF is included in the lens 700.

The lens 700 can be disposed between the lower second electrode 507 and the upper second electrode 801 in each of the sub-pixels PX1, PX2, and PX3. The lens 700 disposed in the first sub-pixel PX1 can be provided as a first color filter CF_R_4, and the first color filter CF_R_4 can block light of colors other than red (R) light. The lens 700 disposed in the second sub-pixel PX2 can be provided as a second color filter CF_G_4, and the second color filter CF_G_4 can block light of colors other than green (G) light. The lens 700 disposed in the third sub-pixel PX3 can be provided as a third color filter CF_B_4, and the third color filter CF_B_4 can block light of colors other than blue (B) light. However, various embodiments of the present disclosure are not limited thereto.

Since the color filters CF_R_4, CF_G_4, and CF_B_4 are disposed between the upper second electrode 801 and the lower second electrode 507, the color filters CF_R, CF_G, and CF_B (see FIG. 3) may not be disposed on the encapsulation layer 900. However, various embodiments of the present disclosure are not limited thereto, and the color filters CF_R, CF_G, and CF_B (see FIG. 3) can be disposed on the encapsulation layer 900 in the sub-pixels PX1, PX2, and PX3, respectively.

Since the remaining parts have been described above in FIGS. 3 and 4, the detailed descriptions thereof will be omitted below.

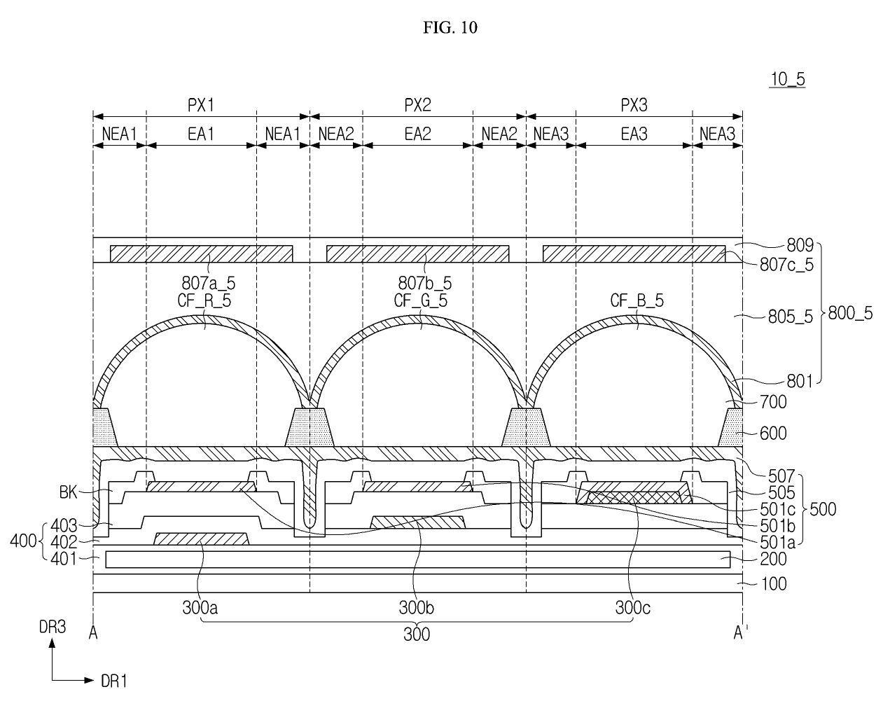

FIG. 10 is a cross-sectional view along line A-A’ of a pixel of a display device according to yet another embodiment of the present disclosure. For example, line A-A’ of FIG. 10 is a different example of line A-A’ of FIG. 3.

Referring to FIG. 10, a pixel 10_5 according to the present embodiment of the present disclosure differs from pixels 10_2 and 10_4 according to FIGS. 7 and 9 in that the lens 700 includes the color filter CF and a thickness of a second common light-emitting layer 805_5 differs in the light-emitting area EA and the non-light-emitting area NEA.

The lens 700 can be disposed between the lower second electrode 507 and the upper second electrode 801 in each of the sub-pixels PX1, PX2, and PX3. The lens 700 disposed in the first sub-pixel PX1 can be provided as a fourth color filter CF_R_5 that emits red (R) light, the lens 700 disposed in the second sub-pixel PX2 can be provided as a fifth color filter CF_G_5 that emits green (G) light, and the lens 700 disposed in the third sub-pixel PX3 can be provided as a sixth color filter CF_B_5 that emits blue (B) light. However, various embodiments of the present disclosure are not limited thereto.

Since the color filters CF_R_5, CF_G_5, and CF_B_5 are disposed between the upper second electrode 801 and the lower second electrode 507, the color filters CF_R, CF_G, and CF_B (see FIG. 3) may not be disposed on the encapsulation layer 900. However, various embodiments of the present disclosure are not limited thereto, and the color filters CF_R, CF_G, and CF_B (see FIG. 3) can be disposed on the encapsulation layer 900 in the sub-pixels PX1, PX2, and PX3, respectively.

The second common light-emitting layer 805_5 can be disposed on the upper second electrode 801, and the second common light-emitting layer 805_5 can be disposed to fill the spaces between the upper second electrodes 801 formed convexly upward in each of the sub-pixels PX1, PX2, and PX3. Accordingly, the lens 700 and a surface formed convexly by the upper second electrode 801 can be planarized by the second common light-emitting layer 805_5. The second common light-emitting layer 805_5 can be formed by a soluble (solution-processable) method in which a solid organic material is converted into a solution to form a film, as described above, and a thickness of a hole transport layer of the second common light-emitting layer 805_5 can be adjusted to control the step between the light-emitting area EA and the non-light-emitting area NEA.

Upper first electrodes 807a_5, 807b_5, and 807c_5 can be disposed on the second common light-emitting layer 805_5 in the sub-pixels PX1, PX2, and PX3, respectively, and the insulating layer 809 can be disposed between the upper first electrodes 807a_5, 807b_5, and 807c_5. The insulating layer 809 can insulate the upper first electrodes 807a_5, 807b_5, and 807c_5.

Since the remaining parts have been described above with reference to FIGS. 3, 4, 7, and 9, the detailed descriptions thereof will be omitted below.

In the display device according to various embodiments of the present disclosure, the organic light-emitting element is disposed in a dual structure, and the lens are disposed between the two organic light-emitting elements. Accordingly, the light resonance effect can occur on the lens and can also occur between the organic light-emitting element and the reflective electrode that are disposed thereunder, and the connection electrode between the lenses can reflect light to redirect the light path toward the center, thereby achieving a light-condensing effect and improving optical efficiency.

In the display device according to various embodiments of the present disclosure, the organic light-emitting element can be disposed in a dual structure, thereby increasing overall luminance, and by arranging the RGB OLED in one of the dual organic light-emitting elements, insufficient color components can be compensated for, thereby improving color reproducibility.

In the display device according to various embodiments of the present disclosure, it is possible to enhance optical efficiency and reduce power consumption through light-condensing and resonance effects, thereby achieving the low-power display device.

However, effects obtainable from the present disclosure are not limited to the above-described effects, and other effects that are not mentioned will be able to be clearly understood by those skilled in the art to which the present disclosure pertains from the following description.

Although various embodiments of the present disclosure have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments of the present disclosure are illustrative and not restrictive in all respects. In addition, the scope of various embodiments of the present is determined by the appended claims rather than detailed description. In addition, the meaning and scope of the claims and all changed or modified forms derived from the equivalent concept thereof should be construed as being included in the scope of various embodiments of the present disclosure.

### DESCRIPTION OF REFERENCE NUMERALS

1: display device
10: pixel PX: sub-pixel
100: substrate
200: circuit part
300: reflective electrode
400: insulating layer
500: first organic light-emitting element
501: lower first electrode
505: first common light-emitting layer
505a, 505b, 505c: organic layers
507: lower second electrode
600: auxiliary electrode
700: lens
800: second organic light-emitting element
801: upper second electrode
805: second common light-emitting layer
807: upper first electrode
900: encapsulation layer
CF: color filter
GR: grid part
BK: bank
300a’, 300b’, 300c’: connection electrodes

What is claimed is:

1. A display device comprising:
a substrate having at least one sub-pixel including a light-emitting area and a non-light-emitting area around the light-emitting area;
a first organic light-emitting element over the substrate in the light-emitting area;
a second organic light-emitting element over the first organic light-emitting element; and
a lens between the first organic light-emitting element and the second organic light-emitting element.

2. The display device of claim 1, wherein the first organic light-emitting element includes a lower first electrode, a first common light-emitting layer over the lower first electrode, and a lower second electrode over the first common light-emitting layer.

3. The display device of claim 2, wherein the second organic light-emitting element includes an upper second electrode, a second common light-emitting layer over the upper second electrode, and an upper first electrode over the second common light-emitting layer.

4. The display device of claim 3, wherein the upper second electrode is disposed between the lens and the second common light-emitting layer, and
wherein the second common light-emitting layer is disposed between the upper second electrode and the upper first electrode.

5. The display device of claim 3, wherein the lens is in direct contact with the lower second electrode and the upper second electrode.

6. The display device of claim 3, further comprising an auxiliary electrode disposed over the non-light-emitting area,
wherein the auxiliary electrode connects the lower second electrode to the upper second electrode.

7. The display device of claim 6, wherein the auxiliary electrode is in direct contact with the lens.

8. The display device of claim 3, wherein a thickness of the second common light-emitting layer between adjacent sub-pixels is greater than a thickness of the second common light-emitting layer in the light-emitting area.

9. The display device of claim 3, wherein the second common light-emitting layer includes a first light-emitting layer configured to emit light of a first wavelength, a second light-emitting layer configured to emit light of a second wavelength, or a third light-emitting layer configured to emit light of a third wavelength.

10. The display device of claim 2, wherein the at least one sub-pixel includes a first sub-pixel, a second sub-pixel, and a third sub-pixel,
wherein the first sub-pixel includes a first reflective electrode between the substrate and the lower first electrode, the second sub-pixel includes a second reflective electrode between the substrate and the lower first electrode, and the third sub-pixel includes a third reflective electrode between the substrate and the lower first electrode,
wherein a separation distance between the first reflective electrode and the lower second electrode is greater than a separation distance between the second reflective electrode and the lower second electrode, and
wherein the separation distance between the second reflective electrode and the lower second electrode is greater than a separation distance between the third reflective electrode and the lower second electrode.

11. The display device of claim 1, further comprising a circuit part between the first organic light-emitting element and the substrate,
wherein the first organic light-emitting element and the circuit part are electrically connected in the non-light-emitting area.

12. The display device of claim 11, wherein the second organic light-emitting element and the circuit part are electrically connected in the non-light-emitting area.

13. The display device of claim 1, further comprising a color filter over the second organic light-emitting element.

14. The display device of claim 1, wherein the first organic light-emitting element includes organic layers separately disposed in each of the at least one sub-pixel including a plurality of sub-pixels, and
wherein the second organic light-emitting element includes a second common light-emitting layer disposed across the plurality of sub-pixels.

15. The display device of claim 14, wherein the organic layers include a first organic layer configured to emit light of a fourth wavelength, a second organic layer configured to emit light of a fifth wavelength, and a third organic layer configured to emit light of a sixth wavelength.

16. The display device of claim 1, further comprising an auxiliary electrode disposed over the non-light-emitting area,
wherein the auxiliary electrode is in direct contact with the lens.

17. A display device comprising:
a substrate having at least one sub-pixel including a light-emitting area and a non-light-emitting area around the light-emitting area;
a first organic light-emitting element over the substrate in the light-emitting area;
a second organic light-emitting element over the first organic light-emitting element; and
a color filter between the first organic light-emitting element and the second organic light-emitting element.

18. The display device of claim 17, wherein the at least one sub-pixel includes a first sub-pixel, a second sub-pixel, and a third sub-pixel, and
wherein the color filter includes a first color filter disposed in the first sub-pixel, a second color filter disposed in the second sub-pixel, and a third color filter disposed in the third sub-pixel.

19. The display device of claim 18, wherein each of the first color filter, the second color filter, and the third color filter has a lens shape which is convex upward, or functions as a lens.

20. The display device of claim 17, further comprising an auxiliary electrode disposed over the non-light-emitting area,
wherein the auxiliary electrode is in direct contact with the color filter.
